(19) United States
(12) Patent Application Publication
(10) Pub. No.: US 2024/0047621 A1
(43) Pub. Date: Feb. 8, 2024

(54) LED CHIP

(71) Applicant: Xiamen San'an Optoelectronics Co., Ltd., Xiamen (CN)

(72) Inventors: Min HUANG, Xiamen (CN); Xiaoliang LIU, Xiamen (CN); Anhe HE, Xiamen (CN)

(21) Appl. No.: 18/489,155

(22) Filed: Oct. 18, 2023

Related U.S. Application Data
(63) Continuation of application No. PCT/CN2021/088496, filed on Apr. 20, 2021.

(51) Int. Cl. H01L 33/46

(52) U.S. Cl. CPC H01L 33/46

(57) ABSTRACT

Provided is an LED chip, which includes a semiconductor stack layer and an insulating layer on the semiconductor stack layer. The insulating layer at least includes a first insulating layer and a second insulating layer. The insulating layer has a step structure including a first step formed by the first insulating layer and a second step formed by the second insulating layer. The first step extends beyond the second step in a horizontal direction. Since the insulating layer is formed by at least the first insulating layer and the second insulating layer, crack or whole-layer breaking of the insulating layer is avoided. The extended portion of the first insulating layer can play a buffering role, thereby reducing a stress generated inside the second structural layer, avoiding the second structural layer from cracking or whole-layer breaking, and improving the reliability of the LED chip.

### TECHNICAL FIELD

The present disclosure relates to the technical field of light emitting diodes (LED), and particularly to an LED chip.

### BACKGROUND

An LED chip is widely used in various fields due to its high reliability, long service life and low power consumption. An insulating layer of the LED chip is mostly a single-layer silicon oxide layer with a large thickness. Since an end or a through hole of the single-layer silicon oxide layer has a large slope, when another structural layer is formed on the single-layer silicon oxide layer, a large stress will be generated inside the another structural layer, which leads to cracking or whole-layer breaking of the another structural layers, and thus reduces the reliability of the LED chip.

### SUMMARY

An objective of the present disclosure is to provide an LED chip, in which an insulating layer is formed by at least a first insulating layer and a second insulating layer, and the first insulating layer extends beyond the second insulating layer by a predetermined length in a horizontal direction, so as to reduce a stress generated in a second structural layer when the second structural layer is formed on the second insulating layer, avoid the second structural layer from cracking or whole-layer breaking under the stress, and improve the reliability of the LED chip.

In one aspect, an embodiment of the present disclosure provides an LED chip, the LED chip includes a semiconductor stack layer, and an insulating layer disposed on the semiconductor stack layer. The insulating layer includes a first insulating layer and a second insulating layer formed on an upper surface of the first insulating layer, the insulating layer has a step structure, the step structure includes a first step formed by the first insulating layer and a second step formed by the second insulating layer, and the first step extends beyond the second step in a horizontal direction.

In an embodiment, a thickness of the second insulating layer is greater than that of the first insulating layer, and the thickness of the second insulating layer is equal to or greater than 1 micrometer (μm).

In an embodiment, in the horizontal direction, a length L₁ of the first step beyond the second step is equal to or greater than 50 nanometers (nm) and less than or equal to 5000 nm.

In an embodiment, when the first insulating layer is an atomic layer deposition layer, the length L₁ of the first step beyond the second step is equal to or greater than 100 nm and less than or equal to 5000 nm; when the first insulating layer is a high-density plasma chemical vapor deposition (HDPCVD) layer, the length L₁ of the first step beyond the second step is equal to or greater than 50 nm and less than or equal to 100 nm.

In an embodiment, a density of the first insulating layer is greater than a density of the second insulating layer, and a length L₁ of the first step beyond the second step is in direct proportion to a difference between the density of the first insulating layer and the density of the second insulating layer.

In an embodiment, an angle α₁ between a side surface of the first step and the horizontal direction is smaller than an angle α₂ between a side surface of the second step and the horizontal direction.

In an embodiment, a side surface of the second step is a slope surface, and an angle α₂ between the slope surface and the horizontal direction is in a range from 20° to 40°, 40° to 60°, or 60° to 70°.

In an embodiment, angles α₁ between a side surface of the first step and the horizontal direction decrease in a vertical direction, and the angles α₁ are in a range from 10° to 30°, or 30° to 45°.

In an embodiment, the insulating layer is provided with a through hole penetrating there through, and a sidewall of the through hole forms the step structure; and an end portion of the insulating layer is provided with the step structure.

In an embodiment, the first insulating layer is an atomic layer deposition layer, and a thickness of the first insulating layer is in a range from 30 nm to 200 nm; and a second insulating layer is one of an HDPCVD layer, a plasma enhanced chemical vapor deposition (PECVD) layer, or an evaporation deposition layer.

In an embodiment, the first insulating layer is an HDPCVD layer, and a thickness of the first insulating layer is in a range from 400 nm to 1000 nm; and the second insulating layer is an evaporation deposition layer.

In an embodiment, the first insulating layer and the second insulating layer are prepared by the same preparation process, and preparation materials of the first insulating layer and the second insulating layer are different; the preparation materials of the first insulating layer and the second insulating layer include one or more selected from the group consisting of silicon oxide, silicon nitride, silicon oxynitride, aluminum oxide, and titanium oxide.

In an embodiment, the first insulating layer is made of aluminum oxide.

In an embodiment, the second insulating layer is a distributed Bragg reflector (DBR).

In an embodiment, the insulating layer further comprises a third insulating layer formed on an upper surface of the second insulating layer; the step structure further comprises a third step formed by the third insulating layer; a length L₂ of the second step beyond the third step in the horizontal direction is smaller than a length L₁ of the first step beyond the second step in the horizontal direction.

In an embodiment, a second structural layer is formed on a surface of the second insulating layer facing away from the first insulating layer; an elongation δ of the second structural layer is equal to or less than 50%; and the second structural layer is made of one of nickel, gold, titanium, chromium, indium tin oxide, titanium oxide, silicon oxide, aluminum oxide, silicon nitride, titanium nitride, or aluminum nitride.

In an embodiment, a thickness of the second insulating layer is greater than that of the first insulating layer, and a thickness of the third insulating layer is equal to or greater than the thickness of the second insulating layer; and a density of the first insulating layer is greater than that of the second insulating layer, and a density of the third insulating layer is equal to or less than that of the second insulating layer.

In an embodiment, a first structural layer is formed on a surface of the first insulating layer facing away from the second insulating layer, and the first structural layer is one of a transparent insulating layer, a transparent conductive layer, or a metal layer.

In an embodiment, the semiconductor stack layer is used as a first structural layer, the insulating layer is disposed on the first structural layer, and the second insulating layer is disposed to face away from the semiconductor stack layer.

In an embodiment, the LED chip further includes a substrate acting as a first structural layer; and the semiconductor stack layer is disposed on the substrate to form a mesa structure on the substrate, the insulating layer covers at least a sidewall of the semiconductor stack layer and a portion of the substrate not covered by the semiconductor stack layer, and the second insulating layer is disposed to face away from the semiconductor stack layer.

In another aspect, an embodiment of the present disclosure provides an insulating layer, and the insulating layer at least includes a first insulating layer, a second insulating layer disposed on an upper surface of the first insulating layer, and a step structure. The step structure includes a first step formed by the first insulating layer and a second step formed by the second insulating layer, and the first step extends beyond the second step in a horizontal direction.

In an embodiment, a thickness of the second insulating layer is greater than that of the first insulating layer, and the thickness of the second insulating layer is equal to or greater than 1 μm.

In an embodiment, a length L₁ of the first step beyond the second step is equal to or greater than 50 nm and less than or equal to 5000 nm.

In an embodiment, the first insulating layer is an atomic layer deposition layer, a length L₁ of the first step beyond the second step is equal to or greater than 100 nm and less than or equal to 5000 nm.

In an embodiment, the first insulating layer is an HDPCVD layer, the length L₁ of the first step beyond the second step is equal to or greater than 50 nm and less than or equal to 100 nm.

In an embodiment, an angle α₁ between a side surface of the first step and the horizontal direction is smaller than an angle α₂ between a side surface of the second step and the horizontal direction.

In an embodiment, a side surface of the second step is a slope surface, and an angle α₂ between the slope surface and the horizontal direction is in a range from 20° to 40°, 40° to 60°, or 60° to 70°.

In an embodiment, angles α₁ between a side surface of the first step and the horizontal direction decrease in a vertical direction, and the angles α₁ are in a range from 10° to 30°, or 30° to 45°.

In an embodiment, the insulating layer is provided with a through hole penetrating there through, and a sidewall of the through hole forms the step structure; and an end portion of the insulating layer is provided with the step structure.

In an embodiment, the first insulating layer is an atomic layer deposition layer, and a thickness of the first insulating layer is in a range from 30 nm to 200 nm; and a second insulating layer is one of an HDPCVD layer, a PECVD layer, or an evaporation deposition layer.

In an embodiment, the first insulating layer is an HDPCVD layer, and a thickness of the first insulating layer is in a range from 400 nm to 1000 nm; and the second insulating layer is an evaporation deposition layer.

In an embodiment, the first insulating layer and the second insulating layer are prepared by the same preparation process, and preparation materials of the first insulating layer and the second insulating layer are different; the preparation materials of the first insulating layer and the second insulating layer include one or more selected from the group consisting of silicon oxide, silicon nitride, silicon oxynitride, aluminum oxide, and titanium oxide.

In an embodiment, the first insulating layer is made of aluminum oxide.

In an embodiment, the second insulating layer is a DBR.

In an embodiment, the insulating layer further includes a third insulating layer formed on an upper surface of the second insulating layer; the step structure further includes a third step formed by the third insulating layer; a length L₂ of the second step beyond the third step in the horizontal direction is smaller than a length L₁ of the first step beyond the second step in the horizontal direction.

### BENEFICIAL EFFECTS

Compared with the related art, the present disclosure has at least the following beneficial effects.

In the present disclosure, the insulating layer is formed by at least the first insulating layer and the second insulating layer, which can avoid crack or whole-layer breaking of the insulating layer and improve the reliability of the insulating layer. In addition, the first insulating layer extends beyond the second insulating layer by a predetermined length in the horizontal direction, as such, when a subsequent second structural layer is formed on the insulating layer, the extended portion can play a buffering role, thereby reducing a stress generated inside the second structural layer, avoiding the second structural layer from cracking or whole-layer breaking under the stress, and improving the reliability of the LED chip. In addition, if the extended portion of the first insulating layer beyond the second insulating layer in the horizontal direction is located at an end of the insulating layer, the extended portion can also block the entry of water vapor, thereby avoiding the aging failure of the LED chip.

### BRIEF DESCRIPTION OF DRAWINGS

In order to explain the technical solutions of the embodiments of the present disclosure more clearly, the following accompanying drawings will be briefly introduced. It should be understood that the following accompanying drawings merely show some embodiments of the present disclosure, so they should not be regarded as limiting the scope of protection of the present disclosure. For the skilled in the art, other relevant drawings can be obtained according to these accompanying drawings without creative work.

FIG. 1 illustrates a schematic cross-sectional view of an LED chip according to an embodiment of the present disclosure.

FIG. 2 illustrates a schematic cross-sectional view of an LED chip according to an embodiment of the present disclosure.

FIG. 3 illustrates a schematic cross-sectional view of an LED chip according to an embodiment of the present disclosure.

FIG. 4 illustrates a schematic cross-sectional view of an LED chip according to an embodiment of the present disclosure.

FIG. 5 illustrates a schematic cross-sectional view of an LED chip according to an embodiment of the present disclosure.

FIG. 6 illustrates a schematic cross-sectional view of an LED chip according to an embodiment of the present disclosure.

FIGS. 7a-7b illustrate a schematic cross-sectional view of an LED chip according to an embodiment of the present disclosure, in which, FIG. 7a illustrates a schematic overall structural view of the LED chip, and FIG. 7b illustrates an enlarged view of a dashed block area in FIG. 7a.

FIGS. 8a-8b illustrate a schematic cross-sectional view of an LED chip according to an embodiment of the present disclosure, in which, FIG. 8a illustrates a schematic overall structural view of the LED chip, and FIG. 8b illustrates an enlarged view of a dashed block area in FIG. 8a.

FIGS. 9a-9b illustrate a schematic cross-sectional view of an LED chip according to an embodiment of the present disclosure, in which, FIG. 9a illustrates a schematic overall structural view of the LED chip, and FIG. 9b illustrates an enlarged view of a dashed block area in FIG. 9a.

FIGS. 10a-10b illustrate a schematic cross-sectional view of an LED chip according to an embodiment of the present disclosure, in which, FIG. 10a illustrates a schematic overall structural view of the LED chip, and FIG. 10b illustrates an enlarged view of a dashed block area in FIG. 10a.

FIG. 11 illustrates a schematic cross-sectional view of an insulating layer according to an embodiment of the present disclosure.

FIG. 12 illustrates a schematic cross-sectional view of an insulating layer according to an embodiment of the present disclosure.

FIG. 13 illustrates a schematic cross-sectional view of an insulating layer according to an embodiment of the present disclosure.

FIG. 14 illustrates a schematic cross-sectional view of an insulating layer according to an embodiment of the present disclosure.

### DESCRIPTION OF REFERENCE SYMBOLS

10: insulating layer; 11: first insulating layer; 12: second insulating layer; 13: third insulating layer; 14: step structure; 20: first structural layer; 30: second structural layer; 40: semiconductor stack layer; 50: substrate; 110: substrate; 120: semiconductor stack layer; 121: first type semiconductor layer; 122: active layer; 123: second type semiconductor layer; 130: current blocking layer; 140: transparent conductive layer; 151: first electrode; 152: second electrode; 160: protective layer; 171: first pad; 172: second pad; 210: substrate; 220: semiconductor stack layer; 221: first type semiconductor layer; 222: active layer; 223: second type semiconductor layer; 230: transparent conductive layer; 240: reflective layer; 251: first electrode; 252: second electrode; 260: first protective layer; 271: first pad; 272: second pad; 280: second protective layer; 310: substrate; 320: semiconductor stack layer; 321: first type semiconductor layer; 322: active layer; 323: second type semiconductor layer; 330: transparent conductive layer; 340: first protective layer; 350: reflective layer; 360: second protective layer; 370: first electrode; 380: second electrode; 390: third protective layer; 410: substrate; 420: semiconductor stack layer; 421: first type semiconductor layer; 422: active layer; 423: second type semiconductor layer; 430: current blocking layer; 440: transparent conductive layer; 451: first electrode; 452: second electrode; 453: interconnection electrode; 460: protective layer; 471: first pad; 472: second pad.

### DETAILED DESCRIPTION OF EMBODIMENTS

The following describes the implementation of the present disclosure through specific embodiments, and the skilled in the art can easily understand other advantages and effects of the present disclosure from the contents disclosed in this specification. The present disclosure can also be implemented or operated through different specific embodiments, and various details in the present disclosure can be modified or changed based on different viewpoints and applications without departing from the spirit of the present disclosure.

In the description of the present disclosure, it should be noted that orientation or position relationship indicated by terms “upper”, “lower” and “height” is based on orientation or position relationship shown in the accompanying drawings, or is orientation or position relationship of the products of the present disclosure during using, only for the convenience of describing the present disclosure and simplifying the description, and does not indicate or imply that devices or elements referred to must have a specific orientation, or must be constructed and operated in a specific orientation, so it cannot be understood as limiting of the present disclosure.

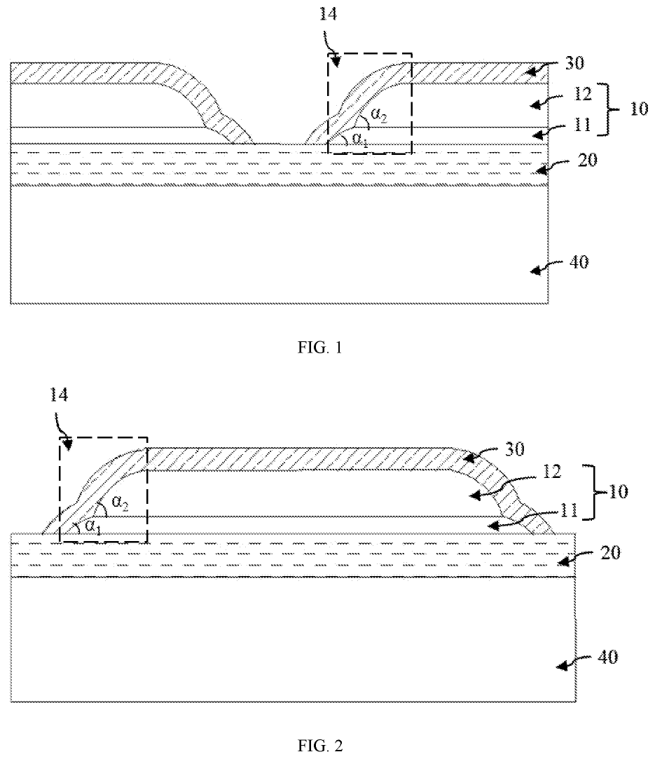

According to one aspect of the present disclosure, an LED chip is provided. Referring to FIGS. 1 and 2, the LED chip includes a semiconductor stack layer 40 and an insulating layer 10. The insulating layer 10 includes at least a first insulating layer 11 and a second insulating layer 12 formed on an upper surface of the first insulating layer 11. The insulating layer 10 has a step structure 14. The step structure 14 includes a first step formed by the first insulating layer 11 and a second step formed by the second insulating layer 12. The first step extends beyond the second step in a horizontal direction, in other words, the first insulating layer 11 extends beyond the second insulating layer 12 in the horizontal direction.

The insulating layer 10 is formed by at least the first insulating layer 11 and the second insulating layer 12, which can prevent the insulating layer 10 from cracking or whole-layer breaking and improve the reliability of the insulating layer 10. Moreover, the first insulating layer 11 extends beyond the second insulating layer 12 by a predetermined length in the horizontal direction, as such, when a second structural layer 30 is formed on the insulating layer 10, the extended portion can play a buffering role, thereby reducing a stress generated inside the second structural layer 30, avoiding the second structural layer 30 from cracking or whole-layer breaking under the stress, and improving the reliability of the LED chip.

In an illustrated embodiment, referring to FIGS. 1 and 2, a first structural layer 20 is formed on a surface of the insulating layer 10 facing towards the semiconductor stack layer 40, and the first structural layer 20 is one of a transparent insulating layer, a transparent conductive layer, or a metal layer. A second structural layer 30 is formed on a surface of the insulating layer 10 facing away from the semiconductor stack layer 40 and covers an upper surface of the insulating layer 10 and the step structure 14. An elongation δ of the second structural layer 30 is equal to or less than 50%. According to elongations δ of metals, i.e., an elongation of aluminum is 70.92%, an elongation of silver is 54.38%, an elongation of copper is 53.2%, an elongation of nickel is 48.4%, an elongation of gold is 35%, an elongation of platinum (Pt) is 24.2%, an elongation of titanium (Ti) is 24.94%, chromium platinum 20.99%, an elongation of tungsten platinum 8.84%, a preparation material of the second structural layer 30 may be selected as one of nickel, gold, titanium, chromium (Cr), indium tin oxide, titanium oxide, silicon oxide, aluminum oxide, silicon nitride, titanium nitride, or aluminum nitride.

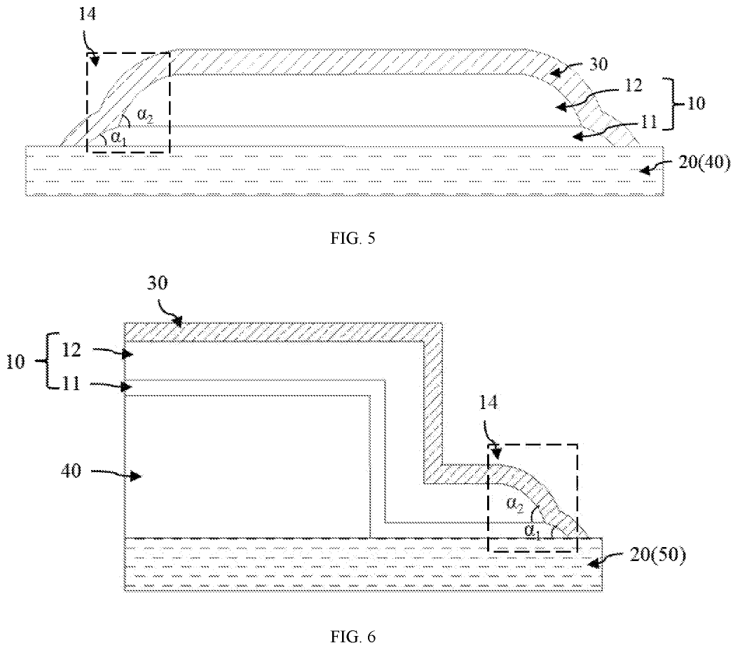

As an alternative embodiment, referring to FIG. 5, a semiconductor stack layer 40 acts as a first structural layer 20, the insulating layer 10 is formed on the semiconductor stack layer 40, and the second insulating layer 12 is disposed to face away from the semiconductor stack layer 40.

As an alternative embodiment, referring to FIG. 6, the LED chip further includes a substrate 50. The substrate 50 is used as the first structural layer 20, and the semiconductor stack layer 40 forms a mesa structure on the substrate 50, the insulating layer 10 covers at least a sidewall of the semiconductor stack layer 40 and a portion of the substrate 50 not covered by the semiconductor stack layer 40; and the second insulating layer 12 is disposed to facing away from the semiconductor stack layer 40.

In an illustrated embodiment, a thickness of the second insulating layer 12 is greater than that of the first insulating layer 11, and the thickness of the second insulating layer 12 is equal to or greater than 1 micrometer (μm). Because the second insulating layer 12 has a large thickness, the second step has a large slope. When the second structural layer 30 is formed on the second step, a portion of the first step beyond the second step can act better buffer effect for the second structural layer 30, thereby reducing a stress generated inside the second structural layer 30, and avoiding the second structural layer 30 from cracking or whole-layer breaking under the stress.

Referring to FIGS. 1 and 2, an angle α₁ between a side surface of the first step and the horizontal direction is smaller than an angle α₂ between a side surface of the second step and the horizontal direction. In a preferable embodiment, angles α₁ between the side surface of the first step and the horizontal direction decrease in a vertical direction, and the angles α₁ are in a range from 10° to 30°, or 30° to 45°. Further, the side surface of the second step is a slope surface, and an angle α₂ between the slope surface and the horizontal direction is in a range from 20° to 40°, 40° to 60°, or 60° to 70°.

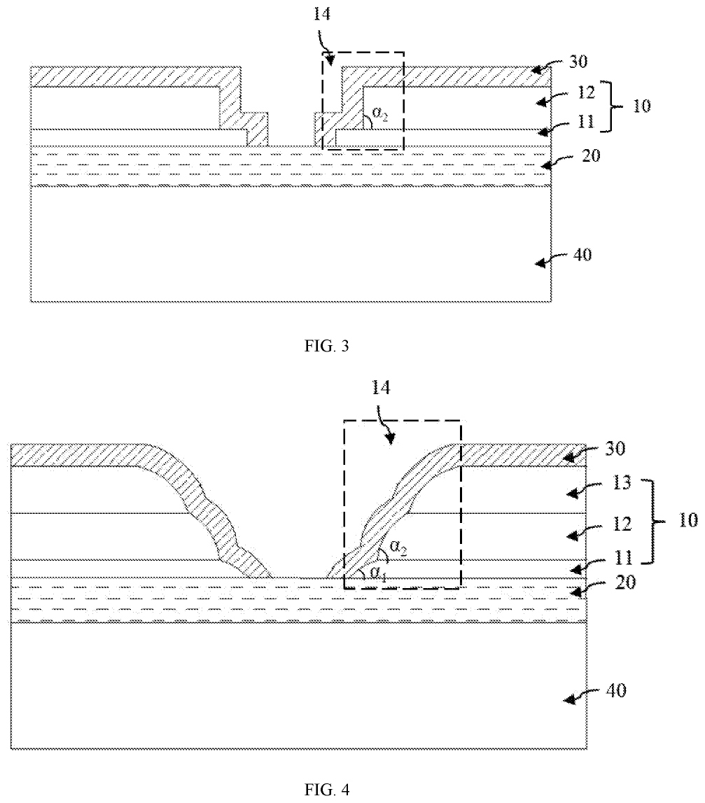

As an alternative embodiment, referring to FIG. 3, the side surfaces of the first step and the second step are vertical surfaces.

In an illustrated embodiment, referring to FIGS. 1 and 2, the step structure 14 is located at an end portion or middle portion of the insulating layer 10. The insulating layer 10 is provided with a through hole penetrating there through, and a sidewall of the through hole is configured as the step structure 14 (FIG. 1). The end portion of the insulating layer 10 is provided with the step structure 14 (FIG. 2). When the step structure 14 is located at the end portion of the insulating layer 10, the portion of the first insulating layer 11 beyond the second insulating layer 12 in the horizontal direction can block the entry of water vapor and avoid the aging failure of the LED chip.

In an illustrated embodiment, preparation materials of each of the first insulating layer 11 and the second insulating layer 12 include one or more selected from the group consisting of silicon oxide, silicon nitride, silicon oxynitride, aluminum oxide, and titanium oxide. In an illustrated embodiment, the first insulating layer 11 is made of aluminum oxide, and the first insulating layer 11 made of aluminum oxide has good water resistance. The second insulating layer 12 is a distributed Bragg reflector (DBR).

In an illustrated embodiment, the first insulating layer 11 is an atomic layer deposition layer; and the thickness of the first insulating layer 11 is in a range from 30 nm to 200 nm, preferably, the thickness of the first insulating layer 11 is in a range from 30 nm to 100 nm, or in a range from 100 nm to 150 nm, or in a range from 150 nm to 200 nm. In another illustrated embodiment, the first insulating layer 11 is a high-density plasma chemical vapor deposition (HDPCVD) layer; and the thickness of the first insulating layer 11 is in a range from 400 nm to 1000 nm, preferably the thickness of the first insulating layer 11 is in a range from 400 nm to 600 nm, or in a range from 600 nm and 800 nm, or in a range from 800 nm and 1000 nm.

In an illustrated embodiment, a density (i.e., consistency) of the first insulating layer 11 is greater than a maximum density of the second insulating layer 12. The first insulating layer 11 and the second insulating layer 12 can be prepared by different processes, and the preparation materials can be the same or different. For example, when the first insulating layer 11 is an atomic layer deposition layer, the second insulating layer 12 is one of an HDPCVD layer, a plasma chemical vapor deposition (PECVD) layer, or an evaporation deposition layer. When the first insulating layer 11 is an HDPCVD layer, the second insulating layer 12 is an evaporation deposition layer. Alternatively, the first insulating layer 11 and the second insulating layer 12 may also be prepared by the same preparation process, and the preparation materials of the first insulating layer 11 and the second insulating layer 12 are different. For example, both the first insulating layer 11 and the second insulating layer 12 are atomic layer deposition layers, or both the first insulating layer 11 and the second insulating layer 12 are HDPCVD layers.

Since the density of the first insulating layer 11 is greater than the maximum density of the second insulating layer 12, when the insulating layer 10 is etched by a dry etching method or a wet etching method, an etching rate to the first insulating layer 11 is lower than an etching rate to the second insulating layer 12, so a step structure 14 is formed on the insulating layer 10. Specifically, the dry etching method may be an inductively coupled plasma (ICP) method.

In an illustrated embodiment, referring to FIGS. 1 to 3, in the horizontal direction, a length L₁ of the first step beyond the second step is equal to or greater than 50 nm and less than or equal to 5000 nm. The length L₁ is related to the density of the first insulating layer 11 and the second insulating layer 12. The greater the difference in density between the first insulating layer 11 and the second insulating layer 12, the greater the length L₁ will be. For example, when the first insulating layer 11 is an atomic layer deposition layer, the length L₁ is equal to or greater than 100 nm and less than or equal to 5000 nm. When the first insulating layer 11 is an HDPCVD layer, the length L₁ is equal to or greater than 50 nm and less than or equal to 100 nm.

In an illustrated embodiment, referring to FIG. 4, the insulating layer 10 further includes a third insulating layer 13 formed on an upper surface of the second insulating layer 12, and correspondingly, the step structure 14 further includes a third step formed by the third insulating layer 13. A length L₂ of the second step beyond the third step in the horizontal direction is smaller than the length L₁ of the first step beyond the second step.

A thickness of the third insulating layer 13 is equal to or greater than that of the second insulating layer 12, and a density of the third insulating layer 13 is equal to or less than a minimum density of the second insulating layer 12. The third insulating layer 13, the first insulating layer 11, and the second insulating layer 12 can be prepared by different processes, for example, the first insulating layer 11 is an atomic layer deposition layer, the second insulating layer 12 is an HDPCVD layer, and the third insulating layer 13 is an evaporation deposition layer. Alternatively, the third insulating layer 13, the first insulating layer 11 and the second insulating layer 12 may also be prepared by the same preparation process, and the third insulating layer 13, the first insulating layer 11, and the second insulating layer 12 are made of different materials.

The LED chip of the present disclosure was tested under different conditions to verify the reliability of the LED chip.

The LED chip of the present disclosure was subjected to aging tests under different conditions: 1) 85° C.+1500 mA; 2) 115° C.+1500 mA; 3) high temperature and high humidity; 4) double 85° C.+15 mA, and 5) cold and hot cycles at a temperature of −45° C.-125° C., the tested LED chips all have high reliability.

### Embodiment 1

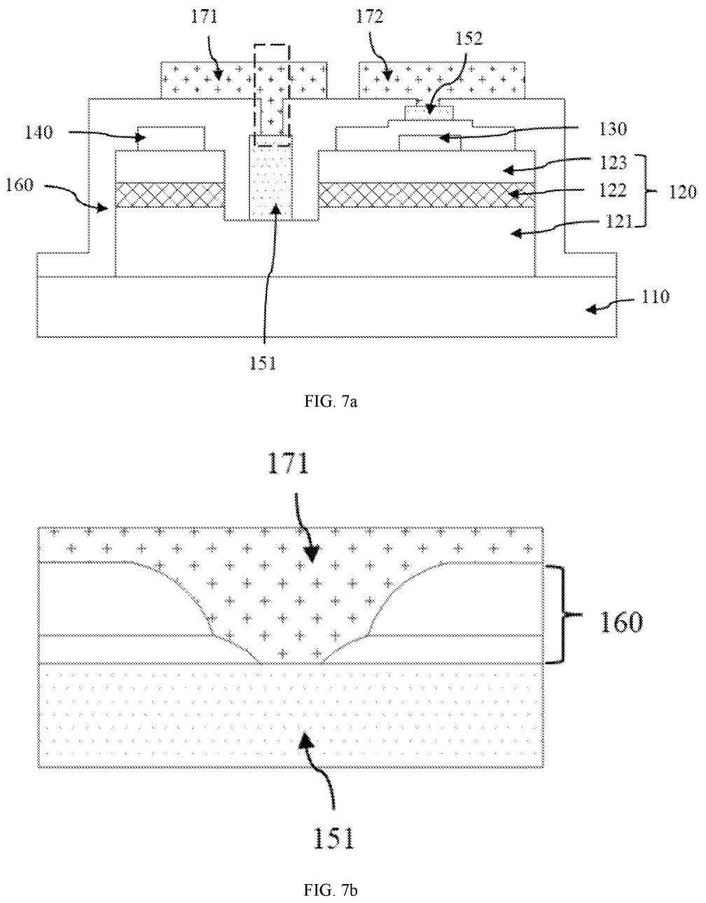

Referring to FIGS. 7a-7b, the embodiment 1 provides an LED chip with flip-chip structure. FIG. 7a illustrates a schematic overall structural view of the LED chip, and FIG. 7b illustrates an enlarged view of a dashed block area in FIG. 7a. The LED chip includes a substrate 110 and a semiconductor stack layer 120 disposed on an upper surface of the substrate 110. The semiconductor stack layer 120 forms a mesa structure on the upper surface of the substrate 110. The semiconductor stack layer 120 includes a first type semiconductor layer 121, an active layer 122, and a second type semiconductor layer 123 sequentially arranged from bottom to top, the semiconductor stack layer 120 is provided with a groove extending from the second type semiconductor layer 123 into the first type semiconductor layer 121, and a portion of the first type semiconductor layer 121 is exposed from the groove.

Specifically, the first type semiconductor layer 121 is an n-type semiconductor layer, the second type semiconductor layer 123 is a p-type semiconductor layer, the active layer 122 is a multi-layer quantum well layer, and the substrate 110 is a sapphire flat bottom substrate or a sapphire patterned substrate.

Illustratively, the LED chip may further include a current blocking layer 130, a transparent conductive layer 140, an electrode layer, a protective layer 160, and a pad layer arranged in sequence. The current blocking layer 130 is formed on an upper surface of the second type semiconductor layer 123, and a length of the transparent conductive layer 140 is greater than that of the current blocking layer 130, so that the transparent conductive layer 140 can covers an upper surface and sidewalls of the current blocking layer 130. The electrode layer includes a first electrode 151 electrically connected to the first type semiconductor layer 121, and a second electrode 152 electrically connected to the second type semiconductor layer 123. The pad layer includes a first pad 171 electrically connected to the first electrode 151, and a second pad 172 electrically connected to the second electrode 152. The protective layer 160 covers an upper surface and sidewalls of the semiconductor stack layer 120 and a region of the upper surface of the substrate 110 not covered by the semiconductor stack layer 120.

Specifically, the electrode layer corresponds to the first structural layer, the pad layer corresponds to the second structural layer, and the protective layer 160 corresponds to the insulating layer. The protective layer 160 is provided with through holes at positions corresponding to the first electrode 151 and the second electrode 152. The first pad 171 fills the through hole and is electrically connected to the first electrode 151, and the second pad 172 fills the through hole and is electrically connected to the second electrode 152. As shown in FIG. 7b, sidewalls of the through holes in the protective layer 160 is configured in the above-mentioned step structure.

Illustratively, the current blocking layer 130 is made of silicon oxide, specifically, a preparation material of the current blocking layer 130 includes one or more of silicon oxide, silicon nitride, silicon carbide, or silicon oxynitride.

Illustratively, the transparent conductive layer 140 is made of a conductive material with transparent properties. In this embodiment, the transparent conductive layer 140 is made of indium tin oxide, which mainly plays the role of ohmic contact and lateral current expansion.

Illustratively, the first electrode 151 and the second electrode 152 are made of aurum (Au) or an alloy of Au. The structure and preparation material of the protective layer 160 are the same as those of the insulating layer provided in the above embodiment.

### Embodiment 2

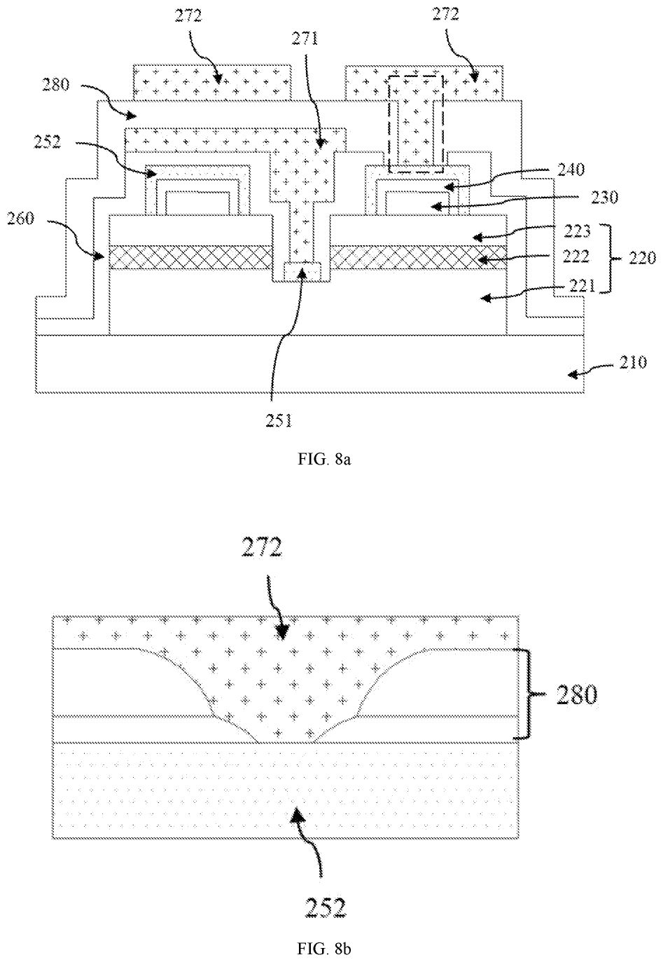

Referring to FIGS. 8a-8b, the embodiment 2 provides another LED chip with flip-chip structure. FIG. 8a illustrates a schematic overall structural view of the LED chip, and FIG. 8b illustrates an enlarged view of a dashed block area in FIG. 8a. The LED chip includes a substrate 210 and a semiconductor stack layer 220 disposed on an upper surface of the substrate 210. The semiconductor stack layer 220 forms a mesa structure on the upper surface of the substrate 210. The semiconductor stack layer 220 includes a first type semiconductor layer 221, an active layer 222, and a second type semiconductor layer 223 sequentially arranged from bottom to top, the semiconductor stack layer 220 is provided with a groove extending from the second type semiconductor layer 223 into the first type semiconductor layer 221, and a portion of the first type semiconductor layer 221 is exposed from the groove.

Specifically, the first type semiconductor layer 221 is an n-type semiconductor layer, the second type semiconductor layer 223 is a p-type semiconductor layer, the active layer 222 is a multi-layer quantum well layer, and substrate 210 is a sapphire flat bottom substrate or a sapphire patterned substrate.

In an illustrated embodiment, the LED chip further includes a transparent conductive layer 230, a reflective layer 240, an electrode layer, a first protective layer 260, a first pad 271, a second protective layer 280, and a second pad 272, which are sequentially arranged. The transparent conductive layer 230 is formed on an upper surface of the second type semiconductor layer 223, and a length of the reflective layer 240 is longer than that of the transparent conductive layer 230, so that the reflective layer 240 can cover an upper surface and sidewalls of the transparent conductive layer 230. The electrode layer includes a first electrode 251 electrically connected to the first type semiconductor layer 221, and a second electrode 252 electrically connected to the second type semiconductor layer 223.

The first pad 271 is electrically connected to the first electrode 251, and the second pad 272 is electrically connected to the second electrode 252. An upper surface of the first pad 271 is lower than an upper surface of the second pad 272 in height, and the second protective layer 280 is formed between the first pad 271 and the second pad 272. The second pad 272 is continuously or intermittently disposed on an upper surface of the second protective layer 280. The first protective layer 260 and the second protective layer 280 both cover an upper surface and sidewalls of the semiconductor stack layer 220 and a region of the upper surface of the substrate 210 that is not covered by the semiconductor stack layer 220.

Specifically, the electrode layer corresponds to the first structural layer, the pad layer (i.e., the first pad 271 and the second pad 272) corresponds to the second structural layer, and the first protective layer 260 and the second protective layer 280 correspond to the insulating layer. The first protective layer 260 is provided with a through hole at a position corresponding to the first electrode 251, and the first pad 271 fills the through hole and is electrically connected to the first electrode 251. The second protective layer 280 is provided with a through hole at a position corresponding to the second electrode 252, and the second pad 272 fills the through hole and is electrically connected to the second electrode 252. As shown in FIG. 8b, a sidewall of the through hole in the second protective layer 280 is configured in the above-mentioned step structure. Similarly, a sidewall of the through hole in the first protective layer 260 is also configured in the above-mentioned step structure.

Illustratively, the transparent conductive layer 230 is made of a conductive material with transparent properties. In this embodiment, the transparent conductive layer 230 is made of indium tin oxide, which mainly plays the role of ohmic contact and lateral current expansion.

Illustratively, the reflective layer 240 is made of silver. The preparation materials of the first electrode 251 and the second electrode 252 include Au or an alloy of Au. The structures and preparation materials of the first protective layer 260 and the second protective layer 280 are the same as those of the insulating layer provided in the above embodiment.

### Embodiment 3

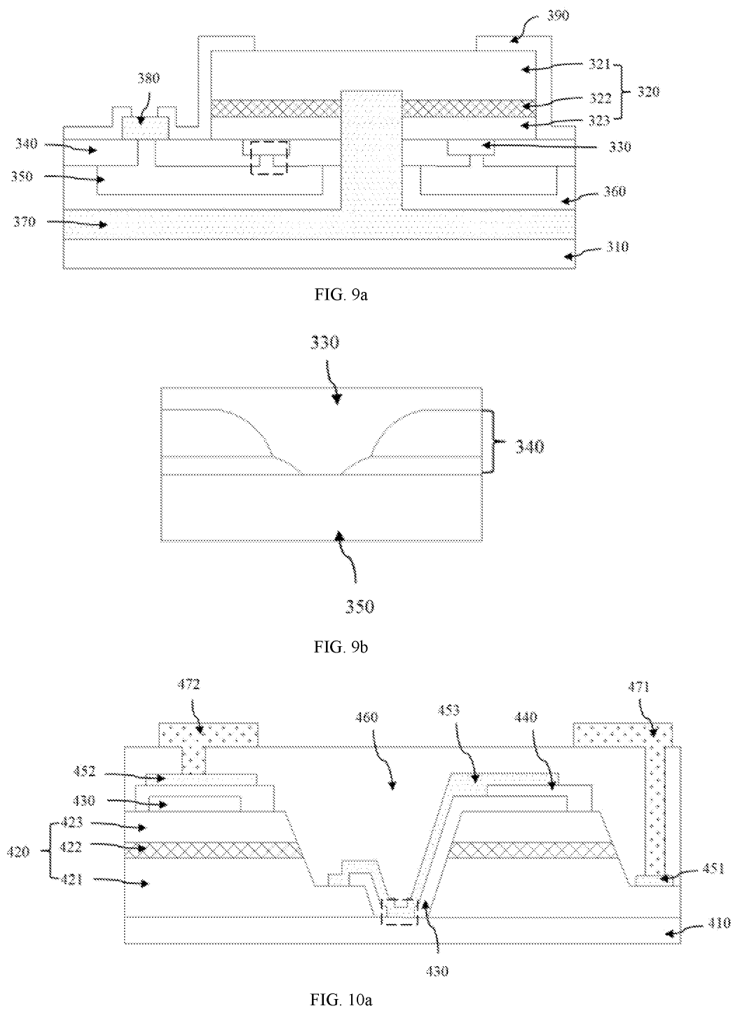

Referring to FIGS. 9a-9b, the embodiment 3 provides an LED chip with vertical structure. FIG. 9a illustrates a schematic overall structural view of the LED chip, and FIG. 9b illustrates an enlarged view of a dashed block area in FIG. 9a. The LED chip includes a substrate 310, a semiconductor stack layer 320, and a functional layer located between the substrate 310 and the semiconductor stack layer 320. Two sides of the semiconductor stack layer 320 are staggered with (i.e., not aligned with) two sides of the substrate 310. Two sides of the functional layer are aligned with the two sides of the substrate 310, that is, the semiconductor stack layer 320 forms a mesa structure on an upper surface of the substrate 310. Part of the surface, sidewalls of the semiconductor stack layer 320, and a portion of the upper surface of the substrate 310 not covered by the semiconductor stack layer 320 are covered with a third protective layer 390. The third protective layer can adopt the insulating layer provided in the above embodiments.

The semiconductor stack layer 320 includes a first type semiconductor layer 321, an active layer 322, and a second type semiconductor layer 323 sequentially arranged from top to bottom. The semiconductor stack layer 320 is provided with a groove extending from the second type semiconductor layer 323 into the first type semiconductor layer 321, and a portion of the first type semiconductor layer 321 is exposed from the groove.

Specifically, the first type semiconductor layer 321 is an n-type semiconductor layer, the second type semiconductor layer 323 is a p-type semiconductor layer, and the active layer 322 is a multi-layer quantum well layer. A preparation material of the substrate 310 is at least one selected from the group consisting of Gallium Arsenide (GaAs), Germanium (Ge), Silicon (Si), Copper (Cu), Molybdenum (Mo), Tungsten Copper (WCu), and Molybdenum Copper (MoCu).

Specifically, the functional layer includes a transparent conductive layer 330, a first protective layer 340, a reflective layer 350, a second protective layer 360, and a first electrode 370 electrically connected to the first type semiconductor layer 321. The transparent conductive layer 330 is connected to the second type semiconductor layer 323, and the first electrode 370 is connected to the substrate 310. An upper surface of the functional layer not be covered by the semiconductor stack layer 320 is provided a second electrode 380 thereon. The first protective layer 340 is provided with an opening for connecting the reflective layer 350 to the second electrode 380, and the reflective layer 350 fills the opening and is electrically connected to the second electrode 380.

Specifically, the transparent conductive layer 330 corresponds to the first structural layer, the reflective layer 350 corresponds to the second structural layer, and the first protective layer 340 corresponds to the insulating layer. A height of the first protective layer 340 is greater than that of the transparent conductive layer 330, and is wrapped around the transparent conductive layer 330 to electrically isolate the transparent conductive layer 330 from the reflective layer 350. A bottom of the first protective layer 340 is provided with a through hole for connecting the reflective layer 350 to the transparent conductive layer 330, and the reflective layer 350 fills the through hole and is electrically connected to the transparent conductive layer 330. As shown in FIG. 9b, a sidewall of the through hole in the first protective layer 340 is configured in the above-mentioned step structure. Similarly, a sidewall of the opening in the first protective layer 340 that connects the reflective layer 350 and the second electrode 380 is also configured in the above-mentioned step structure.

The semiconductor stack layer 320 can correspond to the first structural layer, the third protective layer 390 can correspond to the insulating layer, and other structural layers can be deposited on the third protective layer 390.

Illustratively, the transparent conductive layer 330 is made of a conductive material with transparent properties. In this embodiment, the transparent conductive layer 330 is made of indium tin oxide, which mainly plays the role of ohmic contact and lateral current expansion.

Illustratively, a preparation material of the second electrode 360 may be at least one selected from the group consisting of Au, Ti, aluminum (Al), Cr, Pt, TiW alloy, and Ni. A preparation material of the first electrode 380 includes Au or an alloy of Au.

Illustratively, structures and preparation materials of the first protective layer 340 and the second protective layer 370 are the same as those of the insulating layers provided in the above embodiments.

### Embodiment 4

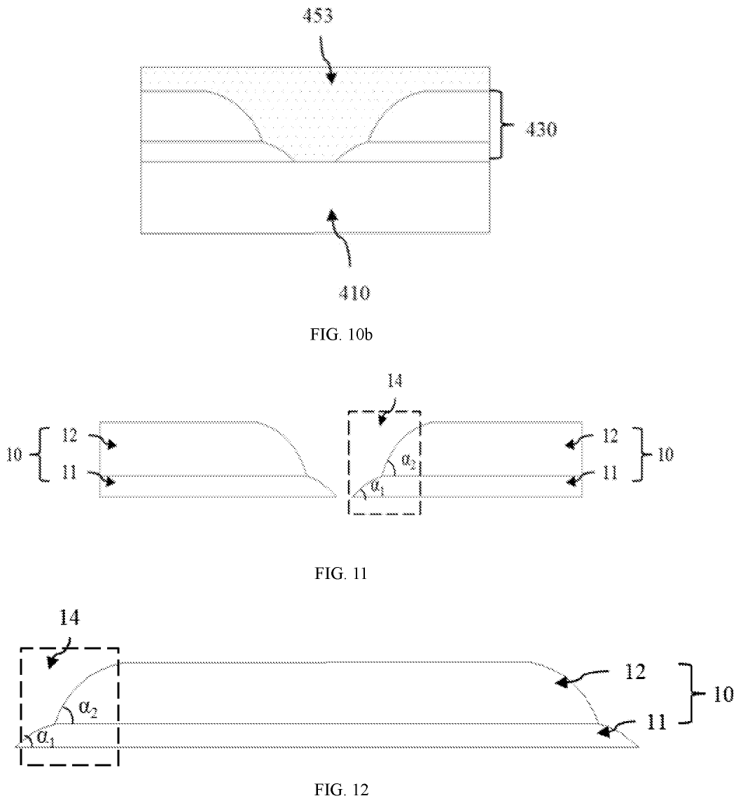

Referring to FIGS. 10a-10b, the embodiment 4 provides an LED chip with high voltage structure. FIG. 10a illustrates a schematic overall structural view of the LED chip, and FIG. 10b illustrates an enlarged view of a dashed block area in FIG. 10a. The LED chip includes a substrate 410 and multiple semiconductor stack layers 420 arranged at intervals, and adjacent semiconductor stack layers 420 are separated by a channel. Each semiconductor stack layer 420 includes a first type semiconductor layer 421, an active layer 422, and a second type semiconductor layer 423 sequentially arranged from bottom to top, and the semiconductor stack layer 420 is provided with a groove extending from the second type semiconductor layer 423 into the first type semiconductor layer 421, and a portion of the first type semiconductor layer 421 is exposed from the groove.

Illustratively, the LED chip may further include a current blocking layer 430, a transparent conductive layer 440, an electrode layer, a protective layer 460 and a pad layer arranged in sequence. The current blocking layer 430 covers an upper surface of the second type semiconductor layer 423, a sidewall of the semiconductor stack layer 420, and part of the channel. The transparent conductive layer 440 covers a portion of the current blocking layer 430. The electrode layer includes a first electrode 451 electrically connected to the first type semiconductor layer 421, a second electrode 452 electrically connected to the second type semiconductor layer 423, and an interconnection electrode 453 connected with the adjacent semiconductor stack layers 420. The pad layer includes a first pad 471 electrically connected to the first electrode 451, and a second pad 472 electrically connected to the second electrode 452. The protective layer 460 covers the upper surface and sidewalls of the semiconductor stack layer 420, and the channel.

Specifically, the substrate 410 corresponds to the first structural layer, the interconnection electrode 453 corresponds to the second structural layer, and the current blocking layer 430 corresponds to the insulating layer. As shown in FIG. 10b, an end portion of the current blocking layer 430 is configured in the above-mentioned step structure.

The first electrode 451 and the second electrode 452 in the electrode layer correspond to the first structural layer, the pad layer corresponds to the second structural layer, and the protective layer 460 corresponds to the insulating layer. The protective layer 460 is provided with through holes at positions corresponding to the first electrode 451 and the second electrode 452. The first pad 471 fills the through hole and is electrically connected to the first electrode 451, and the second pad 472 fills the through hole and is electrically connected to the second electrode 452. Similarly, sidewalls of the through holes in the protective layer 460 are also configured in the above-mentioned step structure.

Illustratively, the current blocking layer 430 is made of silicon oxide, specifically, a preparation material of the current blocking layer 430 includes one or more of silicon oxide, silicon nitride, silicon carbide, or silicon oxynitride.

Illustratively, the transparent conductive layer 440 is made of a conductive material with transparent properties. In this embodiment, the transparent conductive layer 440 is made of indium tin oxide, which mainly plays the role of ohmic contact and lateral current expansion.

Illustratively, the preparation materials of the first electrode 451, the second electrode 452 and the interconnection electrode 453 all include Au or an alloy of Au. The structure and preparation material of the protective layer 460 are the same as those of the insulating layer provided in the above embodiment.

It should be noted that the structures of the LED chips involved in Embodiment 1, Embodiment 2, Embodiment 3 and Embodiment 4 are merely exemplary, and the LED chips claimed in the disclosure are not only the LED chips with flip-chip structure, the LED chip with vertical structure, and the LED chip with high voltage structure mentioned above, but other LED chips are included.

According to another aspect of the present disclosure, an insulating layer is provided. Referring to FIGS. 11 and 12, the insulating layer 10 includes at least a first insulating layer 11 and a second insulating layer 12 formed on an upper surface of the first insulating layer 11. The insulating layer 10 has a step structure 14, and the step structure 14 includes a first step formed by the first insulating layer 11 and a second step formed by the second insulating layer 12. The first step extends beyond the second step in a horizontal direction, in other words, the first insulating layer 11 extends beyond the second insulating layer 12 in the horizontal direction.

The insulating layer 10 is formed by at least the first insulating layer 11 and the second insulating layer 12, which can prevent the insulating layer 10 from cracking or whole-layer breaking and improve the reliability of the insulating layer 10. Moreover, the first insulating layer 11 extends beyond the second insulating layer 12 by a predetermined length in the horizontal direction, as such, when a second structural layer 30 is formed on the insulating layer 10, the extended portion can play a buffering role, thereby reducing a stress generated inside the second structural layer 30, avoiding the second structural layer 30 from cracking or whole-layer breaking under the stress, and improving the reliability of an LED chip using the insulating layer 10.

In an illustrated embodiment, a thickness of the second insulating layer 12 is greater than that of the first insulating layer 11, and the thickness of the second insulating layer 12 is equal to or greater than 1 Because the second insulating layer 12 has a large thickness, the second step has a large slope. When the second structural layer 30 is formed on the second step, a portion of the first step beyond the second step can act better buffer effect for the second structural layer 30, thereby reducing a stress generated inside the second structural layer 30, and avoiding the second structural layer 30 from cracking or whole-layer breaking under the stress.

Referring to FIGS. 11 and 12, an angle α₁ between a side surface of the first step and the horizontal direction is smaller than an angle α₂ between a side surface of the second step and the horizontal direction. In a preferable embodiment, angles α₁ between the side surface of the first step and the horizontal direction decrease in a vertical direction, and the angles α₁ are in a range from 10° to 30°, or 30° to 45°. Further, the side surface of the second step is a slope surface, and an angle α₂ between the slope surface and the horizontal direction is in a range from 20° to 40°, 40° to 60°, or 60° to 70°.

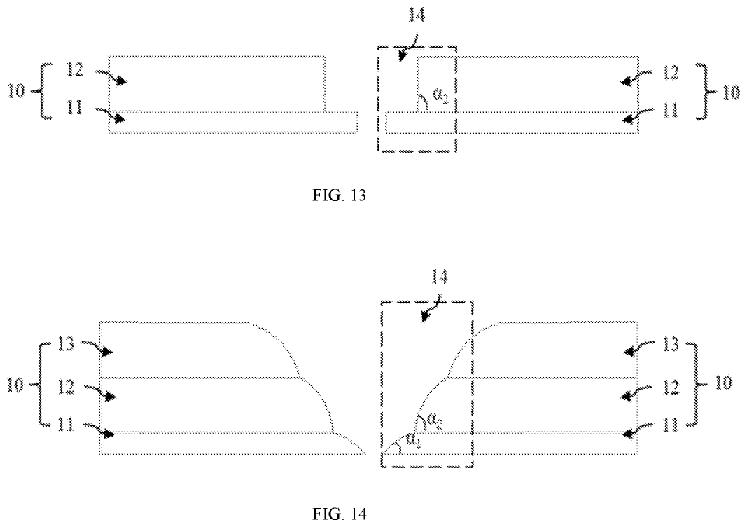

As an alternative embodiment, referring to FIG. 13, the side surfaces of the first step and the second step are vertical surfaces.

In an illustrated embodiment, referring to FIGS. 11 and 12, the step structure 14 is located at an end portion or middle portion of the insulating layer 10. The insulating layer 10 is provided with a through hole penetrating there through, and a sidewall of the through hole is configured as the step structure 14 (FIG. 11). The end portion of the insulating layer 10 is provided with the step structure 14 (FIG. 12). When the step structure 14 is located at the end portion of the insulating layer 10, the portion of the first insulating layer 11 beyond the second insulating layer 12 in the horizontal direction can block the entry of water vapor and avoid the aging failure of the LED chip.

In an illustrated embodiment, preparation materials of each of the first insulating layer 11 and the second insulating layer 12 include one or more selected from the group consisting of silicon oxide, silicon nitride, silicon oxynitride, aluminum oxide, and titanium oxide. In an illustrated embodiment, the first insulating layer 11 is made of aluminum oxide, and the first insulating layer 11 made of aluminum oxide has good water resistance. The second insulating layer 12 is a DBR.

In an illustrated embodiment, the first insulating layer 11 is an atomic layer deposition layer; and the thickness of the first insulating layer 11 is in a range from 30 nm to 200 nm, preferably, the thickness of the first insulating layer 11 is in a range from 30 nm to 100 nm, or in a range from 100 nm to 150 nm, or in a range from 150 nm to 200 nm. In another illustrated embodiment, the first insulating layer 11 is an HDPCVD layer; and the thickness of the first insulating layer 11 is in a range from 400 nm to 1000 nm, preferably the thickness of the first insulating layer 11 is in a range from 400 nm to 600 nm, or in a range from 600 nm and 800 nm, or in a range from 800 nm and 1000 nm.

In an illustrated embodiment, a density of the first insulating layer 11 is greater than a maximum density of the second insulating layer 12. The first insulating layer 11 and the second insulating layer 12 can be prepared by different processes, and the preparation materials can be the same or different. For example, when the first insulating layer 11 is an atomic layer deposition layer, the second insulating layer 12 is one of an HDPCVD layer, a PECVD layer, or an evaporation deposition layer. When the first insulating layer 11 is an HDPCVD layer, the second insulating layer 12 is an evaporation deposition layer. Alternatively, the first insulating layer 11 and the second insulating layer 12 may also be prepared by the same preparation process, and the preparation materials of the first insulating layer 11 and the second insulating layer 12 are different. For example, both the first insulating layer 11 and the second insulating layer 12 are atomic layer deposition layers, or both the first insulating layer 11 and the second insulating layer 12 are HDPCVD layers.

Since the density of the first insulating layer 11 is greater than the maximum density of the second insulating layer 12, when the insulating layer 10 is etched by a dry etching method or a wet etching method, an etching rate to the first insulating layer 11 is lower than an etching rate to the second insulating layer 12, so a step structure 14 is formed on the insulating layer 10. Specifically, the dry etching method may be an ICP method.

In an illustrated embodiment, referring to FIGS. 11 to 13, in the horizontal direction, a length L₁ of the first step beyond the second step is equal to or greater than 50 nm and less than or equal to 5000 nm. The length L₁ is related to the density of the first insulating layer 11 and the second insulating layer 12. The greater the difference in density between the first insulating layer 11 and the second insulating layer 12, the greater the length L₁ will be. For example, when the first insulating layer 11 is an atomic layer deposition layer, the length L₁ is equal to or greater than 100 nm and less than or equal to 5000 nm. When the first insulating layer 11 is an HDPCVD layer, the length L₁ is equal to or greater than 50 nm and less than or equal to 100 nm.

In an illustrated embodiment, referring to FIG. 14, the insulating layer 10 further includes a third insulating layer 13 formed on an upper surface of the second insulating layer 12, and correspondingly, the step structure 14 further includes a third step formed by the third insulating layer 13. A length L₂ of the second step beyond the third step in the horizontal direction is smaller than the length L₁ of the first step beyond the second step.

A thickness of the third insulating layer 13 is equal to or greater than that of the second insulating layer 12, and a density of the third insulating layer 13 is equal to or less than a minimum density of the second insulating layer 12. The third insulating layer 13, the first insulating layer 11, and the second insulating layer 12 can be prepared by different processes, for example, the first insulating layer 11 is an atomic layer deposition layer, the second insulating layer 12 is an HDPCVD layer, and the third insulating layer 13 is an evaporation deposition layer. Alternatively, the third insulating layer 13, the first insulating layer 11 and the second insulating layer 12 may also be prepared by the same preparation process, and the third insulating layer 13, the first insulating layer 11, and the second insulating layer 12 are made of different materials.

According to still another of the present disclosure, a method for preparing the insulating layer in the above embodiments is provided. The preparation method includes the following steps S1 and S2.

In step S1, a first insulating layer 11 and a second insulating layer 12 are prepared. A thickness of the second insulating layer 12 is greater than that of the first insulating layer 11, and the thickness of the second insulating layer 12 is equal to or greater than 1 μm.

A density of the first insulating layer 11 is greater than a maximum density of the second insulating layer 12. The first insulating layer 11 and the second insulating layer 12 can be prepared by different processes, and preparation materials thereof include one or more selected from the group consisting of silicon oxide, silicon nitride, silicon oxynitride, aluminum oxide, an titanium oxide. For example, the first insulating layer 11 is prepared by an atomic layer deposition method, and the second insulating layer 12 is prepared by one of an HDPCVD method, a PECVD, or an evaporation deposition method. Alternatively, the first insulating layer 11 is prepared by a HDPCVD method, and the second insulating layer 12 is prepared by an evaporation deposition method.

Alternatively, the first insulating layer 11 and the second insulating layer 12 may also be prepared by the same preparation process, and the preparation materials of the first insulating layer 11 and the second insulating layer 12 are different. For example, both the first insulating layer 11 and the second insulating layer 12 are prepared by an atomic layer deposition method, or both the first insulating layer 11 and the second insulating layer 12 are prepared by an HDPCVD method.

In an illustrated embodiment, the first insulating layer 11 is made of aluminum oxide, and the first insulating layer 11 made of aluminum oxide has good water resistance. The second insulating layer 12 is a DBR.

In step S2, the insulating layer 10 is etched to form a step structure 14 on the insulating layer 10. The step structure 14 includes a first step formed by the first insulating layer 11 and a second step formed by the second insulating layer 12. The first step extends beyond the second step in a horizontal direction, in other words, the first insulating layer 11 extends beyond the second insulating layer 12 in the horizontal direction.

An angle α₁ between a side surface of the first step and the horizontal direction is smaller than an angle α₂ between a side surface of the second step and the horizontal direction. In a preferable embodiment, angles α₁ between the side surface of the first step and the horizontal direction decrease in a vertical direction, and the angles α₁ are in a range from 10° to 30°, or 30° to 45°. Further, the side surface of the second step is a slope surface, and an angle α₂ between the slope surface and the horizontal direction is in a range from 20° to 40°, 40° to 60°, or 60° to 70°.

As an alternative embodiment, the side surfaces of the first step and the second step are vertical surfaces.

In an illustrated embodiment, in the horizontal direction, a length L₁ of the first step beyond the second step is equal to or greater than 50 nm and less than or equal to 5000 nm. The length L₁ is related to the density of the first insulating layer 11 and the second insulating layer 12. The greater the difference in density between the first insulating layer 11 and the second insulating layer 12, the greater the length L₁ will be. For example, when the first insulating layer 11 is an atomic layer deposition layer, the length L₁ is equal to or greater than 100 nm and less than or equal to 5000 nm. When the first insulating layer 11 is an HDPCVD layer, the length L is equal to or greater than 50 nm and less than or equal to 100 nm.

In another embodiment, in step S1, a first insulating layer 10, a second insulating layer 12 and a third insulating layer 13 are prepared; and in step S2, the first insulating layer 10 is etched to form a step structure 14 on the first insulating layer 10, wherein the step structure 14 further includes a third step formed by the third insulating layer 13. A length L₂ of the second step beyond the third step in the horizontal direction is smaller than the length L₁ of the first step beyond the second step.

As can be seen from the above technical solutions, the insulating layer 10 of the present disclosure is formed by at least the first insulating layer 11 and the second insulating layer 12, which can prevent the insulating layer from cracking or whole-layer breaking and improve the reliability of the insulating layer. Moreover, the first insulating layer 11 extends beyond the second insulating layer 12 by a predetermined length in the horizontal direction, the extended portion can play a buffering role when a second structural layer 30 is formed on the insulating layer 10, thereby reducing the stress generated inside the second structural layer 30, avoiding the second structural layer 30 from cracking or whole-layer breaking under the stress, and improving the reliability of the LED chip. In addition, if the portion of the first insulating layer 11 beyond the second insulating layer 12 in the horizontal direction is located at the end portion of the insulating layer 10, the extended portion can also block the entry of water vapor and avoid the aging failure of the LED chip.

What has been described above is merely the preferred embodiments of the present disclosure. It should be pointed out that some improvements and substitutions can be made by the skilled in the art without departing from the technical principles of the present disclosure, and these improvements and substitutions should also be regarded as the scope of protection of the present disclosure.

What is claimed is:

1. A light emitting diode (LED) chip, comprising a semiconductor stack layer and an insulating layer disposed on the semiconductor stack layer;
wherein the insulating layer comprises a first insulating layer and a second insulating layer formed on an upper surface of the first insulating layer, the insulating layer has a step structure, the step structure comprises a first step formed by the first insulating layer and a second step formed by the second insulating layer, and the first step extends beyond the second step in a horizontal direction.

2. The LED chip as claimed in claim 1, wherein a thickness of the second insulating layer is greater than that of the first insulating layer, and the thickness of the second insulating layer is equal to or greater than 1 micrometer (μm).

3. The LED chip as claimed in claim 1, wherein in the horizontal direction, a length L1 of the first step beyond the second step is equal to or greater than 50 nanometers (nm) and less than or equal to 5000 nm.

4. The LED chip as claimed in claim 1, wherein when the first insulating layer is an atomic layer deposition layer, a length L₁ of the first step beyond the second step is equal to or greater than 100 nm and less than or equal to 5000 nm;
when the first insulating layer is a high-density plasma chemical vapor deposition (HDPCVD) layer, the length L₁ of the first step beyond the second step is equal to or greater than 50 nm and less than or equal to 100 nm.

5. The LED chip as claimed in claim 1, wherein a density of the first insulating layer is greater than a density of the second insulating layer, and a length L₁ of the first step beyond the second step is in direct proportion to a difference between the density of the first insulating layer and the density of the second insulating layer.

6. The LED chip as claimed claim 1, wherein an angle α₁ between a side surface of the first step and the horizontal direction is smaller than an angle α₂ between a side surface of the second step and the horizontal direction.

7. The LED chip as claimed in claim 1, wherein a side surface of the second step is a slope surface, and an angle α₂ between the slope surface and the horizontal direction is in a range from 20° to 40°, 40° to 60°, or 60° to 70°.

8. The LED chip as claimed claim 1, wherein angles α₁ between a side surface of the first step and the horizontal direction decrease in a vertical direction, and the angles α₁ are in a range from 10° to 30°, or 30° to 45°.

9. The LED chip as claimed in claim 1, wherein the insulating layer is provided with a through hole penetrating there through, and a sidewall of the through hole forms the step structure; and
an end portion of the insulating layer is provided with the step structure.

10. The LED chip as claimed in claim 1, wherein the first insulating layer is an atomic layer deposition layer, and a thickness of the first insulating layer is in a range from 30 nm to 200 nm; and
a second insulating layer is one of an HDPCVD layer, a plasma enhanced chemical vapor deposition (PECVD) layer, or an evaporation deposition layer.

11. The LED chip as claimed in claim 1, wherein the first insulating layer is an HDPCVD layer, and a thickness of the first insulating layer is in a range from 400 nm to 1000 nm; and
the second insulating layer is an evaporation deposition layer.

12. The LED chip as claimed in claim 1, wherein the first insulating layer and the second insulating layer are prepared by the same preparation process, and preparation materials of the first insulating layer and the second insulating layer are different; and the preparation materials of the first insulating layer and the second insulating layer comprise one or more selected from the group consisting of silicon oxide, silicon nitride, silicon oxynitride, aluminum oxide, and titanium oxide.

13. The LED chip as claimed in claim 1, wherein the first insulating layer is made of aluminum oxide.

14. The LED chip as claimed in claim 1, wherein the second insulating layer is a distributed Bragg reflector (DBR).

15. The LED chip as claimed in claim 1, wherein the insulating layer further comprises a third insulating layer formed on an upper surface of the second insulating layer; the step structure further comprises a third step formed by the third insulating layer; a length L₂ of the second step beyond the third step in the horizontal direction is smaller than a length L₁ of the first step beyond the second step in the horizontal direction.

16. The LED chip as claimed in claim 1, wherein a second structural layer is formed on a surface of the second insulating layer facing away from the first insulating layer; an elongation δ of the second structural layer is equal to or less than 50%; and the second structural layer is made of one of nickel, gold, titanium, chromium, indium tin oxide, titanium oxide, silicon oxide, aluminum oxide, silicon nitride, titanium nitride, or aluminum nitride.

17. The LED chip as claimed in claim 15, wherein a thickness of the second insulating layer is greater than that of the first insulating layer, and a thickness of the third insulating layer is equal to or greater than the thickness of the second insulating layer; and
a density of the first insulating layer is greater than that of the second insulating layer, and a density of the third insulating layer is equal to or less than that of the second insulating layer.

18. The LED chip as claimed claim 1, wherein a first structural layer is formed on a surface of the first insulating layer facing away from the second insulating layer, and the first structural layer is one of a transparent insulating layer, a transparent conductive layer, or a metal layer.

19. The LED chip as claimed in claim 1, wherein the semiconductor stack layer is used as a first structural layer, the insulating layer is disposed on the first structural layer, and the second insulating layer is disposed to face away from the semiconductor stack layer.

20. The LED chip as claimed in claim 1, further comprising a substrate acting as a first structural layer;
wherein the semiconductor stack layer is disposed on the substrate to form a mesa structure on the substrate, the insulating layer covers at least a sidewall of the semiconductor stack layer and a portion of the substrate not covered by the semiconductor stack layer, and the second insulating layer is disposed to face away from the semiconductor stack layer.
